(19) United States
(12) Patent Application Publication
(10) Pub. No.: US 2022/0359400 A1
(43) Pub. Date: Nov. 10, 2022

(54) SEMICONDUCTOR DEVICE AND METHOD FOR FABRICATING THE SAME

(71) Applicant: SK hynix Inc., Gyeonggi-do (KR)

(72) Inventors: Jin Yul LEE, Gyeonggi-do (KR); Beom Ho Mun, Gyeonggi-do (KR); Seung Woo Jin, Gyeonggi-do (KR); Keum Bum Lee, Gyeonggi-do (KR)

(21) Appl. No.: 17/508,393

(22) Filed: Oct. 22, 2021

(30) Foreign Application Priority Data
May 7, 2021 (KR) 10-2021-0059054

(51) Int. Cl. H01L 23/532; H01L 21/768

(52) U.S. Cl. CPC H01L 23/5329; H01L 21/76832; H01L 21/76834; H01L 27/10814

(57) ABSTRACT

Embodiments of the present invention provide a semiconductor device capable of reducing parasitic capacitance between neighboring conductive lines and a method for fabricating the same. According to an embodiment of the present invention, a semiconductor device comprises: a conductive line formed over a substrate; and a multi-layered spacer covering both sidewalls of the conductive line, wherein the multi-layered spacer is stacked in the order of a diffusion barrier material, boron nitride layer, and an antioxidant material.

### CROSS-REFERENCE TO RELATED APPLICATIONS

The present application claims priority to Korean Patent Application No. 10-2021-0059054, filed on May 7, 2021, which is herein incorporated by reference in its entirety.

### BACKGROUND

### 1. Field

The present invention relates to a semiconductor device and a method for fabricating the same and, more particularly, to a semiconductor device including a low-k bit line spacer, and a method for fabricating the same.

### 2. Description of the Related Art

Recently, as semiconductor devices have become highly integrated, the spacing between wirings such as bit lines has been greatly reduced. Accordingly, parasitic capacitance may occur between wirings. Therefore, there is a need for an improved wiring structure and method for fabricating a semiconductor device capable of reducing parasitic capacitance.

### SUMMARY

Embodiments of the present invention provide a semiconductor device capable of reducing parasitic capacitance between neighboring conductive lines and a method for fabricating the same.

According to an embodiment of the present invention, a semiconductor device comprises: a conductive line formed over a substrate; and a multi-layered spacer covering both sidewalls of the conductive line, wherein the multi-layered spacer is stacked in the order of a diffusion barrier material, boron nitride layer, and an antioxidant material.

According to another embodiment of the present invention, a semiconductor device comprises: a bit line structure extended in a direction on a substrate; and a multi-layered spacer covering both sidewalls of the bit line structure, wherein the multi-layered spacer is stacked in the order of a first boron-free nitride layer, boron nitride layer, and a second boron-free nitride layer.

According to another embodiment of the present invention, a method for fabricating a semiconductor device comprises: forming a conductive line over a substrate; and forming a multi-layered spacer covering both sidewalls of the conductive line, wherein the multi-layered spacer is stacked in the order of a diffusion barrier material, boron nitride layer, and an antioxidant material.

The present invention has an effect of improving the reliability of a semiconductor device.

The present invention reduces the parasitic capacitance of a semiconductor device by applying a bit line spacer having a low dielectric constant.

These and other features of the present invention will become better understood by a person having ordinary skill in the art of the invention from the following detailed description of the invention and the drawings.

### BRIEF DESCRIPTION OF THE DRAWINGS

FIG. 1 is a diagram illustrating a semiconductor device according to an embodiment of the present invention.

FIG. 2 is a diagram illustrating a semiconductor device according to another embodiment of the present invention.

FIG. 3 is a plan view illustrating a semiconductor device according to another embodiment of the present invention.

FIG. 4A is a cross-sectional view taken along line A-A′ of FIG. 3.

FIG. 4B is a cross-sectional view taken along line B-B′ of FIG. 3.

FIGS. 5 to 15 are diagrams illustrating a method for fabricating a semiconductor device according to an embodiment of the present invention.

### DETAILED DESCRIPTION

Various embodiments described herein will be described with reference to cross-sectional views, plane views and block diagrams, which are schematic views of the present invention. Therefore, the structures of the drawings may be modified by fabricating technology and/or tolerances. The embodiments of the present invention are not limited to the specific structures shown in the drawings, but include any changes in the structures that may be produced according to the fabricating process. Also, any regions and shapes of regions illustrated in the drawings having schematic views are intended to illustrate specific examples of structures of regions of the various elements, and are not intended to limit the scope of the invention.

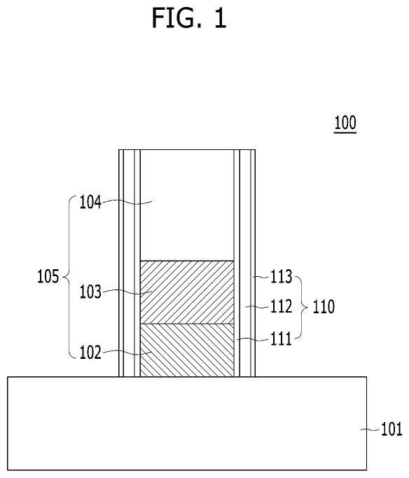

FIG. 1 is a diagram illustrating a semiconductor device according to an embodiment of the present invention.

Referring to FIG. 1, a semiconductor device 100 may include a substrate 101, a pattern structure 105, and dielectric structures 110 formed on both sides of the pattern structure 105.

The pattern structure 105 may be formed on the substrate 101. The pattern structure 105 may further include a first conductive pattern 102 formed on the substrate 101, a second conductive pattern 103 formed on the first conductive pattern 102, and a hard mask pattern 104 formed on the second conductive pattern 103. The first conductive pattern 102 may contact the substrate 10 as shown In FIG. 1. However, in a variation of the embodiment of FIG. 1, the first conductive pattern 102 and the substrate 101 may be electrically separated by a separating material or a dielectric material layer. The first conductive pattern 102 and the second conductive pattern 103 may include polysilicon, metal, metal nitride, metal silicide, or a combination thereof. The hard mask pattern 104 may include a dielectric material.

The dielectric structure 110 may include a multi-layered dielectric material. The dielectric structure 110 may be referred to as a ‘spacer structure’. The dielectric structure 110 may include a stack of a first boron-free nitride layer 111 disposed on both sidewalls of the pattern structure 105, a second boron-free nitride layer 113, and a boron nitride layer 112 disposed between the first boron-free nitride layer 111 and the second boron-free nitride layer 113. The first boron-free nitride layer 111 may contact both opposite sidewalls of the pattern structure 105. In the dielectric structure 110, the first boron-free nitride layer 111, the boron nitride layer 112, and the second boron-free nitride layer 113 may be sequentially stacked in the recited order from the sidewall of the pattern structure 105.

The first boron-free nitride layer 111 may include silicon nitride. For example, the silicon nitride may have the chemical formula Si₃N₄. The first boron-free nitride layer 111 is employed for facilitating a more uniform deposition of the boron nitride layer 112. The first boron-free nitride layer 111 may be referred to as a ‘seed layer’. In addition, the first boron-free nitride layer 111 may prevent the boron in the boron nitride layer 112 from being out-diffused by a thermal process or the like, and may be referred to also as a ‘diffusion barrier layer’.

The thickness of the first boron-free nitride layer 111 may be smaller than the thickness of the second boron-free nitride layer 113. The thickness of the first boron-free nitride layer 111 may be smaller than the thickness of the boron nitride layer 112. For example, the first boron-free nitride layer 111 may be formed to have a thickness of 5 Å to 10 Å.

The second boron-free nitride layer 113 may include the same material as the first boron-free nitride layer 111. The second boron-free nitride layer 113 may include silicon nitride. For example, the silicon nitride may include silicon nitride having the chemical formula Si₃N₄. The second boron-free nitride layer 113 may prevent oxidation and damage of the boron nitride layer 112 due to a thermal process and/or exposure during a semiconductor process, and may be referred to as a ‘capping layer’ or an ‘antioxidation layer’. The thickness of the second boron-free nitride layer 113 may be greater than the thickness of the first boron-free nitride layer 111. The thickness of the second boron-free nitride layer 113 may be equal to or smaller than the thickness of the boron nitride layer 112. For example, the second boron-free nitride layer 113 may have a thickness of 50 Å to 70 Å. In this embodiment of the present invention, the thickness of the second boron-free nitride layer 113 may be smaller than the thickness of the boron nitride layer 112.

The boron nitride layer 112 may include silicon-free nitride. The boron nitride layer 112 may be an amorphous boron nitride layer. The boron nitride layer 112 may have a lower dielectric constant than that of a silicon-containing nitride layer. The boron nitride layer 112 may have a lower dielectric constant than a silicon oxide layer. The boron nitride layer 112 may have a lower dielectric constant than a silicon carbon oxide layer (SiCO).

In the boron nitride layer 112, the boron content in the film may be adjusted to be higher than the nitrogen content. The boron nitride in the boron nitride layer 112 may be in an amorphous form. The thickness of the boron nitride layer 112 may be greater than the thickness of the first boron-free nitride layer 111. The thickness of the boron nitride layer 112 may be equal to or greater than the thickness of the second boron-free nitride layer 113. For example, the boron nitride layer 112 may have a thickness of 50 Å to 100 Å. In this embodiment of the present invention, the thickness of the boron nitride layer 112 may be greater than the thickness of the second boron-free nitride layer 113.

The boron nitride layer 112, the silicon boron nitride SiBN, and the silicon oxide have dielectric constants of 1 to 2, 4 to 5.2, and 3.9 to 4.3, respectively. Thus, a dielectric structure may secure a significantly lower permittivity when the boron nitride layer 112 is applied than when SiBN and/or silicon oxide are applied as the dielectric structure. Accordingly, a parasitic capacitance between neighboring pattern structures 105 may be reduced. In addition, a semiconductor process may be simplified because process difficulty can be significantly lowered than when forming an air gap and because the boron nitride layer 114 has a dielectric constant similar to the air gap.

Moreover, in this embodiment of the present invention, the dielectric structure 110 is formed of multiple spacers in which the first boron-free nitride layer 111, the boron nitride layer 112, and the second boron-free nitride layer 113 are stacked. Accordingly, it is possible to prevent boron in the boron nitride layer 112 from being out-diffused and being oxidized or damaged at the same time.

The thicknesses of the first and second boron-free nitride layers 111 and 113 and the boron nitride layer 112 of the present embodiment described above are presented as an example, and are not intended to limit the scope of the invention only to these ranges. It should be understood that these thicknesses may be adjusted according to various conditions and process requirements within the limit of maintaining the thickness ratio between the spacers.

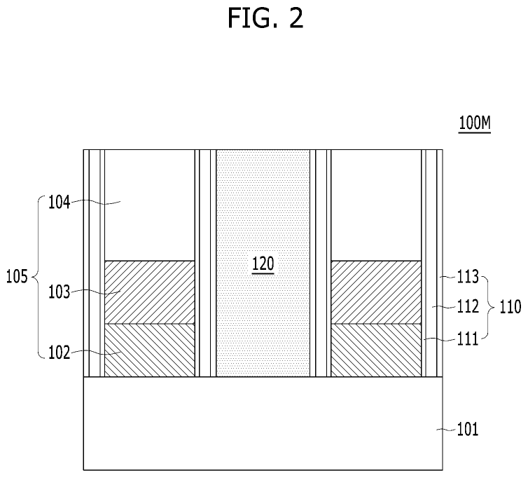

FIG. 2 is a diagram illustrating a semiconductor device according to another embodiment of the present invention. In FIG. 2, the same reference numerals as in FIG. 1 denote the same components. Hereinafter, detailed descriptions of the duplicate components may be omitted.

Referring to FIG. 2, a semiconductor device 100M may include a substrate 101, pattern structures 105 formed on the substrate 101 spaced apart from each other, a plug structure 120 formed between the pattern structures 105, and dielectric structures 110 formed between the pattern structures 105 and the plug structures 120.

A plurality of pattern structures 105 may be formed on the substrate 101. Each of the plurality of pattern structures 105 may include a first conductive pattern 102 formed on the substrate 101, a second conductive pattern 103 formed on the first conductive pattern 102, and a hard mask pattern 104 formed on the second conductive pattern 103. The first conductive pattern 102 may directly contact the substrate 101. The first conductive pattern 102 and the substrate 101 may be electrically separated by a separating material or a dielectric material layer. The first conductive pattern 102 and the second conductive pattern 103 may include polysilicon, metal, metal nitride, metal silicide, or a combination thereof. The hard mask pattern 104 may include a dielectric material.

The dielectric structure 110 may include a multi-layered dielectric material. The dielectric structure 110 may be referred to as a ‘spacer structure’. The dielectric structure 110 may include a stack of a first boron-free nitride layer 111 disposed on both sidewalls of the pattern structure 105, a second boron-free nitride layer 113, and a boron nitride layer 112 disposed between the first and second boron-free nitride layers 111 and 113. The first boron-free nitride layer 111 may contact both sidewalls of the pattern structure 105. In the dielectric structure 110, the first boron-free nitride layer 111, the boron nitride layer 112, and the second boron-free nitride layer 113 may be sequentially stacked in the recited order from the sidewalls of the pattern structure 105.

The first boron-free nitride layer 111 may include silicon nitride. For example, the silicon nitride may include silicon nitride of the chemical formula Si3N4. The first boron-free nitride layer 111 may facilitate the uniform deposition of the boron nitride layer 112 and may be referred to as a ‘seed layer’. In addition, the first boron-free nitride layer 111 may prevent the boron in the boron nitride layer 112 from being out-diffused by a thermal process or the like, and may be referred to also as a ‘diffusion barrier layer’.

The thickness of the first boron-free nitride layer 111 may be smaller than the thickness of the second boron-free nitride layer 113. The thickness of the first boron-free nitride layer 111 may be smaller than the thickness of the boron nitride layer 112. For example, the first boron-free nitride layer 111 may be formed to have a thickness of 5 Å to 10 Å.

The second boron-free nitride layer 113 may include the same material as the first boron-free nitride layer 111. The second boron-free nitride layer 113 may include silicon nitride. For example, the silicon nitride may include silicon nitride of the chemical formula Si₃N₄ (also known as trisilicon tetranitride). The second boron-free nitride layer 113 may prevent oxidation and damage of the boron nitride layer 112 due to a thermal process and/or exposure during a semiconductor process, and may be referred to as a ‘capping layer’ or an ‘antioxidation layer’. The thickness of the second boron-free nitride layer 113 may be greater than the thickness of the first boron-free nitride layer 111. The thickness of the second boron-free nitride layer 113 may be equal to or smaller than the thickness of the boron nitride layer 112. For example, the second boron-free nitride layer 113 may have a thickness of 50 Å to 70 Å. In this embodiment of the present invention, the thickness of the second boron-free nitride layer 113 may be smaller than the thickness of the boron nitride layer 112.

The boron nitride layer 112 may include silicon-free nitride. The boron nitride layer 112 may be an amorphous boron nitride layer. The boron nitride layer 112 may have a lower dielectric constant than that of a silicon-containing nitride. The boron nitride layer 112 may have a lower dielectric constant than silicon oxide. The boron nitride layer 112 may have a lower dielectric constant than silicon carbon oxide (SiCO).

In the boron nitride layer 112, the boron content in the film may be adjusted to be higher than the nitrogen content. The boron nitride layer 112 may be formed in an amorphous form. The thickness of the boron nitride layer 112 may be greater than the thickness of the first boron-free nitride layer 111. The thickness of the boron nitride layer 112 may be equal to or greater than the thickness of second boron-free nitride layer 113. For example, the boron nitride layer 112 may have a thickness of 50 Å to 100 Å. In this embodiment of the present invention, the thickness of the boron nitride layer 112 may be greater than the thickness of the second boron-free nitride layer 113.

In FIG. 2, the semiconductor device 100M may be a part of a memory cell.

In the pattern structures 105, the first conductive pattern 102 may be a bit line contact plug, and the second conductive pattern 103 may include a bit line. The plug structure 120 may include a storage node contact plug.

In another embodiment of the present invention, the first conductive pattern 102 and the second conductive pattern 103 may be a gate electrode of a transistor. The plug structure 120 may be a contact plug connected to a source/drain region of the transistor. The dielectric structure 110 may be a gate spacer or a contact spacer.

The boron nitride layer 112, the SiBN, and the silicon oxide have dielectric constants of 1 to 2, 4 to 5.2, and 3.9 to 4.3, respectively. Thus, a dielectric structure may secure a significantly lower permittivity when the boron nitride layer 112 is applied, than when SiBN and/or silicon oxide are applied as the dielectric structure. Accordingly, parasitic capacitance between neighboring pattern structures 105 may be reduced. In addition, a semiconductor process may be simplified because process difficulty can be significantly lowered than when forming an air gap. It is noted that the boron nitride layer 112 has a dielectric constant similar to the air gap.

Moreover, in this embodiment of the present invention, the dielectric structure 110 is formed as a stack of the first boron-free nitride layer 111, the boron nitride layer 112, and the second boron-free nitride layer 113. Accordingly, it is possible to prevent boron in the boron nitride layer 112 from being out diffused and being oxidized or damaged at the same time.

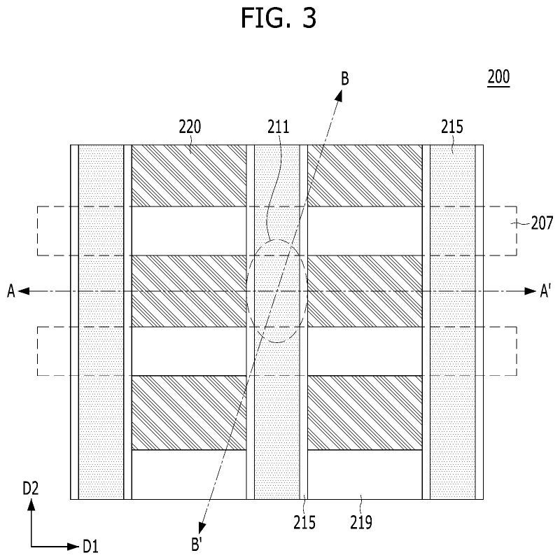

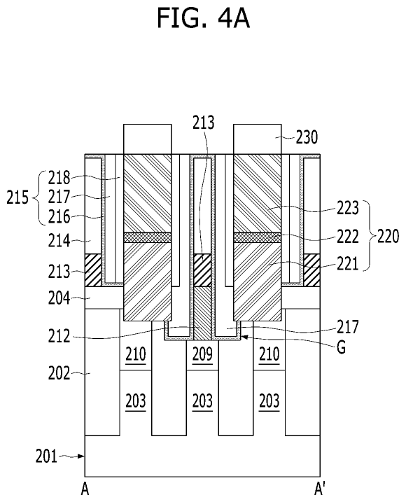

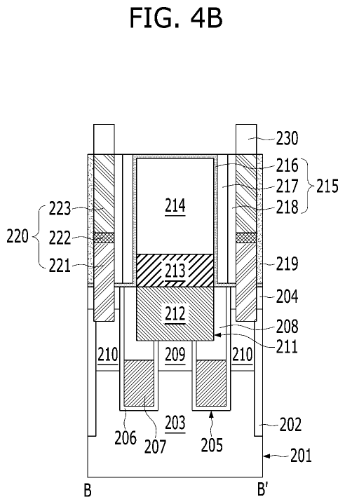

FIG. 3 is a plan view illustrating a semiconductor device according to another embodiment of the present invention. FIG. 4A is a cross-sectional view taken along line A-A′ of FIG. 3. FIG. 4B is a cross-sectional view taken along line B-B′ of FIG. 3.

Referring to FIGS. 3, 4A and 4B, the semiconductor device 200 may include a plurality of memory cells. Each of the memory cells may include a cell transistor including a buried word line 207, a bit line structure, and a memory element 230.

The semiconductor device 200 will be described in detail.

A device isolation layer 202 and an active region 203 may be formed in the substrate 201. A plurality of the active regions 203 may be defined by the device isolation layer 202. The substrate 201 may be made of a material suitable for semiconductor processing. The substrate 201 may include a semiconductor substrate. The substrate 201 may be formed of a material containing silicon. The substrate 201 may include silicon, monocrystalline silicon, polysilicon, amorphous silicon, silicon germanium, monocrystalline silicon germanium, polycrystalline silicon germanium, carbon-doped silicon, a combination thereof, or a multiple-layer thereof. The substrate 201 may also include other semiconductor materials such as germanium. The substrate 201 may include a III/V group semiconductor substrate, for example, a compound semiconductor substrate such as GaAs. The substrate 201 may include a Silicon-On-Insulator (SOI) substrate. The device isolation layer 202 may be formed by a shallow trench isolation (STI) process.

A gate trench 205 may be formed in the substrate 201. A gate dielectric layer 206 is formed on the surface of the gate trench 205. A buried word line 207 may be formed over the gate dielectric layer 206 to partially fill the gate trench 205. A gate capping layer 208 may be formed over the buried word line 207. The upper surface of the buried word line 207 may be located at a lower level than the upper surface of the substrate 201. The buried word line 207 may be made of a low resistive metal material. In the buried word line 207, titanium nitride and tungsten may be sequentially stacked. In another embodiment of the present invention, the buried word line 207 may be formed of titanium nitride only. The buried word line 207 may be referred to as a ‘buried gate electrode’. The buried word line 207 may extend long in a first direction D1.

First and second impurity regions 209 and 210 may be formed in the substrate 201. The first and second impurity regions 209 and 210 may be spaced apart from each other by the gate trench 205. The first and second impurity regions 209 and 210 may be referred to as source/drain regions. The first and second impurity regions 209 and 210 may contain an N-type impurity such as arsenic (As) or phosphorus (P). Accordingly, the buried word line 207 and the first and second impurity regions 209 and 210 may become a cell transistor. The cell transistor may improve a short-channel effect with the buried word line 207.

A bit line contact plug 212 may be formed over the substrate 201. The bit line contact plug 212 may be connected to the first impurity region 209. The bit line contact plug 212 may be disposed inside of the bit line contact hole 211. The bit line contact hole 211 may pass through the hard mask layer 204 and extend to the substrate 201. The hard mask layer 204 may be formed over the substrate 201. The hard mask layer 204 may include a dielectric material. The bit line contact hole 211 may expose the first impurity region 209. The bottom surface of the bit line contact plug 212 may be at a lower position than the upper surfaces of the device isolation layer 202 and the active region 203. The bit line contact plug 212 may be formed of polysilicon or a metal material. A portion of the bit line contact plug 212 may have a line width smaller than the diameter of the bit line contact hole 211. A bit line 213 may be formed over the bit line contact plug 212. A bit line hard mask 214 may be formed over the bit line 213. A stacked structure of the bit line contact plug 212, the bit line 213, and the bit line hard mask 214 may be referred to as a ‘bit line structure’. The bit line 213 may have a line shape extending in the second direction D2 crossing the buried word line 207. A portion of the bit line 213 may be connected to the bit line contact plug 212. When viewed from the A-A′ direction, the bit line 213 and the bit line contact plug 212 may have the same line width. Accordingly, the bit line 213 may extend in the second direction D2 while covering the bit line contact plug 212. The bit line 213 may include a metal material such as tungsten. The bit line hard mask 214 may include a dielectric material such as silicon nitride.

A spacer structure 215 may be formed on a sidewall of the bit line structure. The spacer structure 215 may include a multi-layered dielectric material. The spacer structure 215 may include a stack of a first boron-free nitride layer 216 disposed on both sidewalls of the bit line structure, a second boron-free nitride layer 218, and a boron nitride layer 217 disposed between the first and second boron-free nitride layers 216 and 218.

A storage node contact plug 220 may be formed between neighboring bit line structures. The storage node contact plug 220 may be connected to the second impurity region 210. The storage node contact plug 220 may include a lower plug 221 and an upper plug 223. The storage node contact plug 220 may further include an ohmic contact layer 222 formed between the lower plug 221 and the upper plug 223. The ohmic contact layer 222 may include metal silicide. For example, the lower plug 221 may include polysilicon, and the upper plug 223 may include a metal nitride, a metal material, or a combination thereof.

When viewed in a direction parallel to the bit line structure, a plug separation layer 219 may be formed between neighboring storage node contact plugs 220. The plug separation layer 219 may be formed between neighboring bit line structures. Neighboring storage node contact plugs 220 may be spaced apart from each other by the plug separation layers 219. Between neighboring bit line structures, a plurality of plug separation layers 219 and a plurality of storage node contact plugs 220 may be alternately disposed.

The plug separation layer 219 may include silicon nitride or a low-k material. The plug separation layer 219 may include SiC, SiCO, SiCN, SiOCN, SiBN, or SiBCN.

A memory element 230 may be formed on the upper plug 223. The memory element 230 may include a capacitor including a storage node. The storage node may have a pillar type. A dielectric layer and a plate node may be further formed on the storage node. The storage node may also have different types. For example, the storage node may have a cylinder type other than the pillar type.

A detailed description of the spacer structure 215 may be as follows.

The spacer structure 215 may include a stack of a first boron-free nitride layer 216 disposed on both sidewalls of the bit line structure, a second boron-free nitride layer 218, and a boron nitride layer 217 disposed between the first and second boron-free nitride layers 216 and 218.

The first boron-free nitride layer 216 may extend along the whole structure including the bit line structure. The first boron-free nitride layer 216 may extend from both sidewalls of the bit line structure to the bit line contact hole 211. That is, the first boron-free nitride layer 216 may extend from both sidewalls of the bit line structure into a gap G defined by the bit line contact hole 211 and the bit line contact plug 212.

The first boron-free nitride layer 216 may include silicon nitride. For example, the silicon nitride may include silicon nitride of the chemical formula Si₃N₄. The first boron-free nitride layer 216 may facilitate the uniform deposition of the boron nitride layer 216 and may be referred to as a ‘seed layer’. In addition, the first boron-free nitride layer 216 may prevent boron in the boron nitride layer 217 from being out-diffused by a thermal process or the like, and may be referred to as a ‘diffusion barrier layer’.

The thickness of the first boron-free nitride layer 216 may be smaller than the thickness of the second boron-free nitride layer 218. The thickness of the first boron-free nitride layer 216 may be smaller than the thickness of the boron nitride layer 217. For example, the first boron-free nitride layer 216 may be formed to have a thickness of 5 Å to 10 Å.

The second boron-free nitride layer 218 may have a shorter length in a direction perpendicular to the substrate 201 than the first boron-free nitride layer 216 and the boron nitride layer 217. The bottom surface of the second boron-free nitride layer 218 may be at the same level as the upper surface of the hard mask layer 214. The bottom surface of the second nitride spacer 218 may be at a higher level than the bottom surface of the bit line contact hole 211.

The second boron-free nitride layer 218 may include the same material as the first boron-free nitride layer 216. The second boron-free nitride layer 218 may include silicon nitride. For example, the silicon nitride may include silicon nitride of the chemical formula Si3N4. The second boron-free nitride layer 218 may prevent oxidation and damage of the boron nitride layer 217 due to a thermal process and/or exposure during a semiconductor process, and may be referred to as a ‘capping layer’ or an ‘antioxidation layer’. The thickness of the second boron-free nitride layer 218 may be greater than the thickness of the first boron-free nitride layer 216. The thickness of the second boron-free nitride layer 218 may be equal to or smaller than the thickness of the boron nitride layer 217. For example, the second boron-free nitride layer 218 may have a thickness of 50 Å to 70 Å. In this embodiment of the present invention, the thickness of the second boron-free nitride layer 218 may be smaller than the thickness of the boron nitride layer 217.

The boron nitride layer 217 may be formed to fill a gap G formed by the bit line contact hole 211 and the bit line contact plug 212. That is, the gap G may be gap-filled by the first boron-free nitride layer 216 and the boron nitride layer 217. In detail, a stacked structure of the first boron-free nitride layer 216 and boron nitride layer 217 may be disposed between the bit line contact plug 212 and the storage node contact plug 220 adjacent to the bit line contact plug 212. A stacked structure of the first boron-free nitride layer 216, the boron nitride layer 217, and the second boron-free nitride layer 218 may be disposed between the bit line 213 and the storage node contact plug 220 adjacent to the bit line 213.

The boron nitride layer 217 may include silicon-free nitride. The boron nitride layer 217 may be an amorphous boron nitride layer. The boron nitride layer 217 may have a lower dielectric constant than that of a silicon-containing nitride. The boron nitride layer 217 may have a lower dielectric constant than silicon oxide. The boron nitride layer 217 may have a lower dielectric constant than silicon carbon oxide (SiCO).

In the boron nitride layer 217, the boron content in the film may be adjusted to be higher than the nitrogen content. The boron nitride layer 217 may be formed in an amorphous form. The thickness of the boron nitride layer 217 may be greater than the thickness of the first boron-free nitride layer 216. The thickness of the boron nitride layer 217 may be equal to or greater than the thickness of the second boron-free nitride layer 218. For example, the boron nitride layer 217 may have a thickness of 50 Å to 100 Å. In this embodiment of the present invention, the thickness of the boron nitride layer 217 may be greater than the thickness of the second boron-free nitride layer 218.

Since the boron nitride layer 217 has a dielectric constant of about 1 to 2, a dielectric structure formed of the boron nitride layer 217 may secure a significantly lower permittivity than when SiBN having a dielectric constant of about 4 to 5.2 and/or silicon oxide having a dielectric constant of about 3.9 to 4.3 are applied. Accordingly, parasitic capacitance between the bit line structure and the storage node contact plug 220 adjacent to the bit line structure may be reduced. In addition, the boron nitride layer 217 has a dielectric constant similar to the air gap, which has a dielectric constant of about 1, and may significantly lower the process difficulty compared to forming the air gap, thus simplifying the semiconductor process.

Moreover, in this embodiment of the present invention, the spacer structure 215 is formed by stacking the first boron-free nitride layer 216, the boron nitride layer 217, and the second boron-free nitride layer 218, so that it is possible to prevent boron in the boron nitride layer 217 from being out-diffused, and being oxidized or damaged at the same time.

The thicknesses of the first and second boron-free nitride layers 216 and 218 and the boron nitride layer 217 of the present embodiment described above are an embodiment for comparing the difference in the thickness of each spacer, and the present invention is not limited thereto. The thicknesses of the first and second boron-free nitride layers 216 and 218 and the boron nitride layer 217 may be adjusted according to other conditions and process specification.

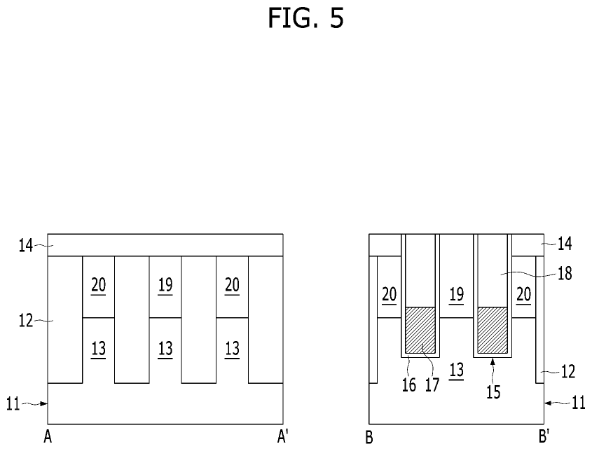

FIGS. 5 to 15 are diagrams illustrating a method for fabricating a semiconductor device according to an embodiment of the present invention. FIGS. 5 to 15 are cross-sectional views illustrating a fabrication method according to cross-sectional views taken along lines A-A′ and B-B′ of FIG. 3.

As shown in FIG. 5, the device isolation layer 12 may be formed in the substrate 11. A plurality of active regions 13 are defined by the device isolation layer 12. The device isolation layer 12 may be formed by a shallow trench isolation (STI) process. The STI process may be as follows. An isolation trench is formed by etching the substrate 11. The isolation trench is filled with a dielectric material, thereby forming the device isolation layer 12. The device isolation layer 12 may include silicon oxide, silicon nitride, or a combination thereof. Chemical vapor deposition (CVD) or other deposition processes may be used to fill the isolation trench with dielectric material. A planarization process such as chemical mechanical polishing (CMP) may be additionally used.

Next, a buried word line structure may be formed in the substrate 11. The buried word line structure may include a gate trench 15, a gate dielectric layer 16 covering the bottom surface and sidewalls of the gate trench 15, a buried word line 17 partially filling the gate trench 15 on the gate dielectric layer 16, and a gate capping layer 18 formed on the buried word line 17.

The method of forming the buried word line structure may be as follows.

First, a gate trench 15 may be formed in the substrate 11. The gate trench 15 may have a line shape crossing the active regions 13 and the device isolation layer 12. The gate trench 15 may be formed by forming a mask pattern (not shown) on the substrate 11 and then performing an etching process using the mask pattern as an etching mask. To form the gate trench 15, the hard mask layer 14 may be used as an etching barrier. The hard mask layer 14 may have a shape patterned by a mask pattern. The hard mask layer 14 may include silicon oxide. The hard mask layer 14 may include TEOS (Tetra Ethyl Ortho Silicate). The bottom surface of the gate trench 15 may be positioned at a higher level than the bottom surface of the device isolation layer 12.

The active region 13 below the gate trench 15 may protrude by recessing a portion of the device isolation layer 12. For example, the device isolation layer 12 below the gate trench 15 may be selectively recessed in the direction of the line B-B′ of FIG. 3. Accordingly, a fin region (a reference numeral is omitted) may be formed under the gate trench 15. The fin region may be a portion of the channel region.

Next, a gate dielectric layer 16 may be formed on the bottom surface and sidewalls of the gate trench 15. Before the gate dielectric layer 16 is formed, etching damage on the surface of the gate trench 15 may be cured. For example, after forming the sacrificial oxide by thermal oxidation treatment, the sacrificial oxide may be removed.

The gate dielectric layer 16 may be formed by thermal oxidation. For example, the gate dielectric layer 16 may be formed by oxidizing the bottom surface and sidewalls of the gate trench 15.

In another embodiment, the gate dielectric layer 16 may be formed by a vapor deposition method such as chemical vapor deposition (CVD) or atomic layer deposition (ALD). The gate dielectric layer 16 may include a high-k material, an oxide, a nitride, an oxynitride, or a combination thereof. The high-k material may include hafnium oxide. The hafnium-containing material may include hafnium oxide, hafnium silicon oxide, hafnium silicon oxynitride, or a combination thereof. In another embodiment, the high-k material may include lanthanum oxide, lanthanum aluminum oxide, zirconium oxide, zirconium silicon oxide, zirconium silicon oxynitride, aluminum oxide, and a combination thereof.

In another embodiment of the present invention, the gate dielectric layer 16 may be formed by depositing liner polysilicon and then radically oxidizing the liner polysilicon layer.

In another embodiment of the present invention, the gate dielectric layer 16 may be formed by radically oxidizing the liner silicon nitride layer after forming the liner silicon nitride layer.

Next, a buried word line 17 may be formed over the gate dielectric layer 16. In order to form the buried word line 17, a recessing process may be performed after forming a conductive layer to fill the gate trench 15. The recessing process may be performed by an etch-back process, or by a sequence of a CMP (chemical mechanical polishing) process and an etch-back process. The buried word line 17 may have a recessed shape that partially fills the gate trench 15. That is, the upper surface of the buried word line 17 may be at a lower level than the upper surface of the active region 13. The buried word line 17 may include a metal, a metal nitride, or a combination thereof. For example, the buried word line 17 may be formed of a titanium nitride (TiN), tungsten (W) or a titanium nitride/tungsten (TiN/W) stack. The titanium nitride/tungsten (TiN/W) stack may have a structure in which the gate trench 15 is partially filled with tungsten after conformally forming titanium nitride. Titanium nitride may be used alone as the buried word line 17, and this may be referred to as a buried word line 17 having a “TiN Only” structure. A double gate structure of a titanium nitride/tungsten (TiN/W) stack and a polysilicon layer may be used as the buried word line 17.

Next, a gate capping layer 18 may be formed over the buried word line 17. The gate capping layer 18 includes a dielectric material. The rest of the gate trench 15 is filled with the gate capping layer 18 over the buried word line 17. The gate capping layer 18 may include silicon nitride. In another embodiment of the present invention, the gate capping layer 18 may include silicon oxide. In another embodiment of the present invention, the gate capping layer 18 may have a NON (Nitride-Oxide-Nitride) structure. The upper surface of the gate capping layer 18 may be at the same level as the upper surface of the hard mask layer 14. To this end, a CMP process may be performed when the gate capping layer 18 is formed.

After the gate capping layer 18 is formed, impurity regions 19 and 20 may be formed. The impurity regions 19 and 20 may be formed by a doping process such as implantation. The impurity regions 19 and 20 may include a first impurity region 19 and a second impurity region 20. The first and second impurity regions 19 and 20 may be doped with impurities of the same conductivity type. The first and second impurity regions 19 and 20 may have the same depth. In another embodiment, the first impurity region 19 may be deeper than the second impurity region 20. The first and second impurity regions 19 and 20 may be referred to as source/drain regions. The first impurity region 19 may be a region to which the bit line contact plug is to be connected. The first impurity region 19 and the second impurity region 20 may be located in different active regions 13. In addition, the first impurity region 19 and the second impurity region 20 may be spaced apart from each other by the gate trenches 15 and positioned in their respective active regions 13.

A cell transistor of a memory cell may be formed by the buried word line 17 and the first and second impurity regions 19 and 20.

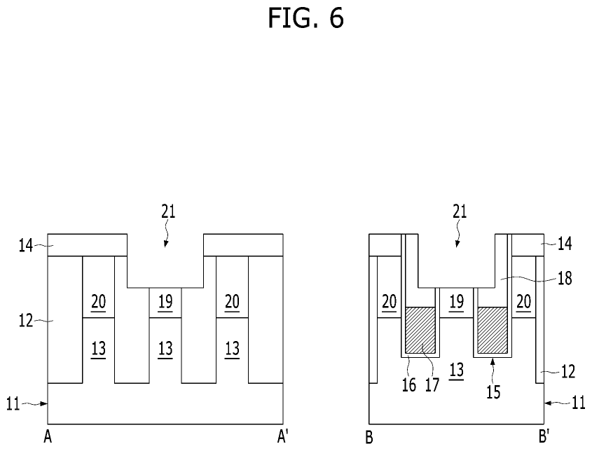

As shown in FIG. 6, a bit line contact hole 21 may be formed. The hard mask layer 14 may be etched using a contact mask to form the bit line contact hole 21. The bit line contact hole 21 may have a circle shape or an ellipse shape when viewed in a plan view. A portion of the substrate 11 may be exposed by the bit line contact hole 21. The bit line contact hole 21 may have a diameter controlled by a predetermined line width. The bit line contact hole 21 may have a shape exposing a portion of the active region 13. For example, the first impurity region 19 is exposed through the bit line contact hole 21. The bit line contact hole 21 has a diameter larger than the width of the minor axis of the active region 13. Accordingly, portions of the first impurity region 19, the device isolation layer 12, and the gate capping layer 18 may be etched in an etching process for forming the bit line contact hole 21. That is, the gate capping layer 18, the first impurity region 19, and the device isolation layer 12 under the bit line contact hole 21 may be recessed by a predetermined depth. Accordingly, the bottom of the bit line contact hole 21 may be expanded into the substrate 11. As the bit line contact hole 21 is expanded, the surface of the first impurity region 19 may be recessed, and the surface of the first impurity region 19 may be positioned at a lower level than the surface of the active region 13.

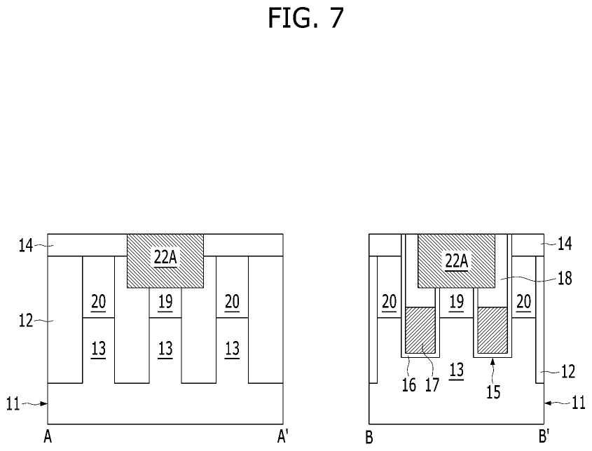

As shown in FIG. 7, a pre-plug 22A is formed. The pre-plug 22A may be formed by selective epitaxial growth (SEG). For example, the pre-plug 22A may include an epitaxial layer doped with phosphorus, for example, SEG SiP. In this way, the pre-plug 22A may be formed without voids by selective epitaxial growth. In another embodiment, the pre-plug 22A may be formed by a polysilicon layer deposition and a CMP process. The pre-plug 22A may fill the bit line contact hole 21. The upper surface of the pre-plug 22A may be at the same level as the upper surface of the hard mask layer 14.

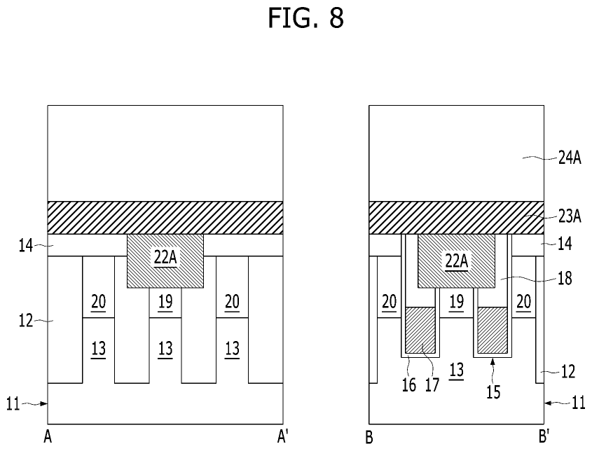

As shown in FIG. 8, a bit line conductive layer 23A and a bit line hard mask layer 24A may be stacked. The bit line conductive layer 23A and the bit line hard mask layer 24A may be sequentially stacked on the pre-plug 22A and the hard mask layer 14. The bit line conductive layer 23A may include a metal-containing material. The bit line conductive layer 23A may include a metal, a metal nitride, a metal silicide, or a combination thereof. In this embodiment, the bit line conductive layer 23A may include tungsten (W). In another embodiment, the bit line conductive layer 23A may include a stack of titanium nitride and tungsten (TiN/W). The titanium nitride may serve as a barrier. The bit line hard mask layer 24A may be formed of a dielectric material having an etch selectivity with respect to the bit line conductive layer 23A and the pre-plug 22A. The bit line hard mask layer 24A may include silicon oxide or silicon nitride. In this embodiment of the present invention, the bit line hard mask layer 24A may be formed of silicon nitride.

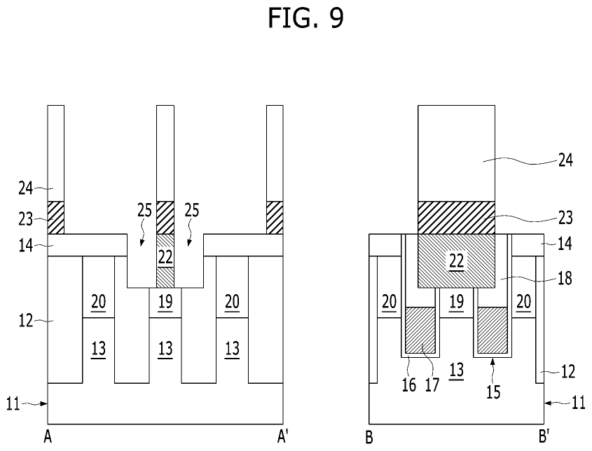

As shown in FIG. 9, a bit line 23 and a bit line hard mask 24 may be formed. The bit line 23 and the bit line hard mask 24 may be formed by an etching process using a bit line mask layer (not shown).

The bit line hard mask layer 24A and the bit line conductive layer 23A are etched by using the bit line mask layer as an etch barrier. Accordingly, the bit line 23 and the bit line hard mask 24 may be formed. The bit line 23 may be formed by etching the bit line conductive layer 23A. The bit line hard mask 24 may be formed by etching the bit line hard mask layer 24A.

Subsequently, the pre-plug 22A may be etched with the same line width as the bit line 23. Accordingly, the bit line contact plug 22 may be formed. The bit line contact plug 22 may be formed over the first impurity region 19. The bit line contact plug 22 may interconnect the first impurity region 19 and the bit line 23. The bit line contact plug 22 may be formed in the bit line contact hole 21. The line width of the bit line contact plug 22 is smaller than the diameter of the bit line contact hole 21. Accordingly, gaps 25 may be defined on both sides of the bit line contact hole 22.

As described above, the gaps 25 are formed in the bit line contact hole 21 since the bit line contact plug 22 is formed. This is because the bit line contact plug 22 is etched and formed to be smaller than the diameter of the bit line contact hole 21. Each gap 25 does not have a shape surrounding the bit line contact plug 22 but each one is independently formed on respective opposite sidewalls of the bit line contact hole 22. As a result, one bit line contact plug 22 and a pair of gaps 25 are disposed in the bit line contact plug hole 2. The pair of gaps 25 is spaced apart from one another by the bit line contact plugs 22. The bottom surface of the gap 25 may extend into the device isolation layer 12. The bottom surface of the gap 25 may be at a lower level than the upper surface of the recessed first impurity region 19.

A structure stacked in the order of the bit line contact plug 22, the bit line 23, and the bit line hard mask 24 may be referred to as a bit line structure. When viewed from a top view, the bit line structure may be a line-shaped pattern structure extended in any one direction.

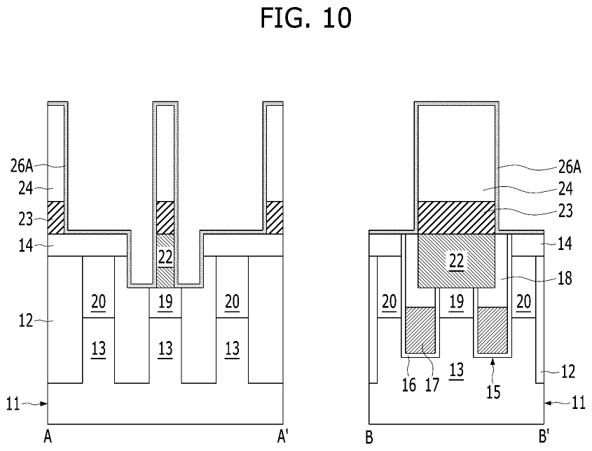

As shown in FIG. 10, a first boron-free nitride pre-layer 26A may be formed. The first boron-free nitride pre-layer 26A may cover the bit line structure. The first boron-free nitride pre-layer 26A may cover both sidewalls of the bit line contact plug 22 and both sidewalls of the bit line 23. The first boron-free nitride pre-layer 26A may cover both sidewalls and upper surface of the bit line hard mask 24.

The first boron-free nitride pre-layer 26A may include a passivation material capable of inhibiting oxidation of the bit line 23. The first boron-free nitride pre-layer 26A may serve as a barrier preventing boron which is to be formed in a subsequent process in the boron nitride layer from being out-diffused by a thermal process or the like. The first boron-free nitride pre-layer 26A may serve as a seed layer for uniform deposition of boron nitride layer to be formed through a subsequent process.

The first boron-free nitride pre-layer 26A may include silicon nitride. For example, the silicon nitride may include silicon nitride of the chemical formula Si₃N₄. The first boron-free nitride pre-layer 26A may be formed to have a minimum thickness capable of preventing the out diffusion of boron. The thickness of the first boron-free nitride pre-layer 26A may be smaller than the thickness of the second boron-free nitride layer to be formed through a subsequent process. The thickness of the first boron-free nitride layer may be smaller than the thickness of the boron nitride layer. For example, the first boron-free nitride pre-layer 26A may be formed to a thickness of 5 Å to 10 Å.

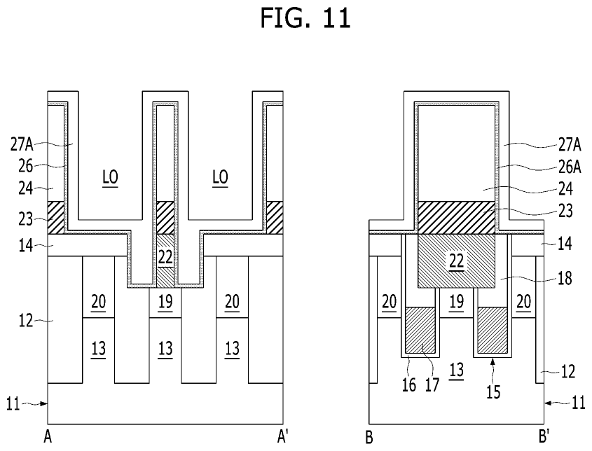

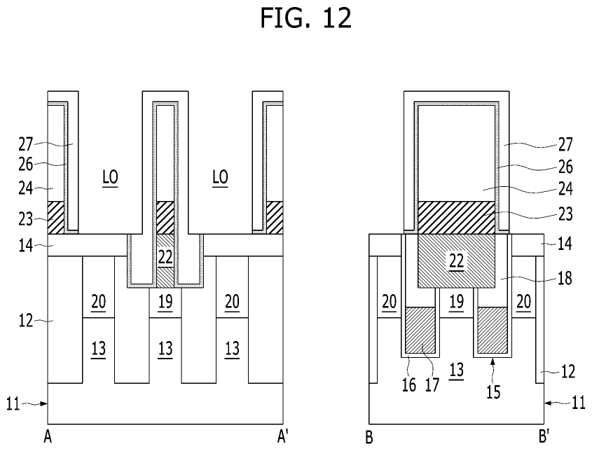

As shown in FIGS. 11 and 12, a boron nitride pre-layer 27A may be formed. The boron nitride pre-layer 27A may be formed on the first boron-free nitride pre-layer 26A. The boron nitride pre-layer 27A may be formed to have a thickness filling the gaps 25. The boron nitride pre-layer 27A may include silicon-free nitride. The boron nitride pre-layer 27A may be an amorphous boron nitride layer. The boron nitride pre-layer 27A may have a lower dielectric constant than silicon-containing nitride. The boron nitride pre-layer 27A have a lower dielectric constant than silicon oxide. The boron nitride pre-layer 27A may have a lower dielectric constant than silicon carbon oxide (SiCO).

The boron nitride pre-layer 27A may be formed in-situ in the same chamber as the first boron-free nitride pre-layer 26A. The boron nitride pre-layer 27A may be formed in a furnace under a low-temperature and low-pressure condition so that the boron content in the film is maintained at a higher ratio than the nitrogen content.

In this embodiment of the present invention, the boron nitride pre-layer 27A may be formed by a low-pressure chemical vapor deposition (LP-CVD) process. The LP-CVD process may use a boron-containing precursor and a nitrogen-containing reactant. For example, the boron-containing precursor may include B₂H₆, and the nitrogen-containing reactant may include ammonia (NH₃). The flow rate of B₂H₆ and NH₃ may be adjusted in the ratio of B₂H₆: NH₃=5 to 7:1. The deposition temperature may be adjusted in the range of 300° C. to 600° C., and the pressure may be adjusted in the range of 0.1 Torr to 1 Torr.

In another embodiment of the present invention, the boron nitride pre-layer 27A may be formed by a plasma enhanced CVD (PE-CVD) process. The PE-CVD process may use borazane (B₂H₆) and BCl₃ as precursors. The method of forming the boron nitride pre-layer 27A is not limited thereto, and process conditions and the like may be adjusted as necessary.

The thickness of the boron nitride layer 27A may be greater than that of the first boron-free nitride pre-layer 26A. The thickness of the boron nitride pre-layer 27A may be the same as the thickness of the second boron-free nitride layer to be formed through a subsequent process, or may be greater than the thickness of the second boron-free nitride layer. For example, the boron nitride pre-layer 27A may have a thickness of 50 Å to 100 Å.

Subsequently, the first boron-free nitride layer 26 and boron nitride layer 27 are formed. The gap 25 may be filled with the first boron-free nitride layer 26 and the boron nitride layer 27.

To this end, the boron nitride pre-layer 27A and the first boron-free nitride pre-layer 26A on the hard mask layer 14 may be etched so that the hard mask layer 14 between the bit line structures is exposed. To etch the boron nitride pre-layer 27A, a fluorocarbon-based dry etching gas may be used. For example, the fluorocarbon-based dry etching gas may contain CF₃.

After the first boron-free nitride layer 26 and the boron nitride layer 27 are formed, a cleaning process for removing by-products of the etching process may be performed. For example, the cleaning process may be performed by wet cleaning using a buffered oxide etchant (BOE) type solution.

As the first boron-free nitride layer 26 and the boron nitride layer 27 are formed, a line-shaped opening LO may be defined between the neighboring bit lines 23.

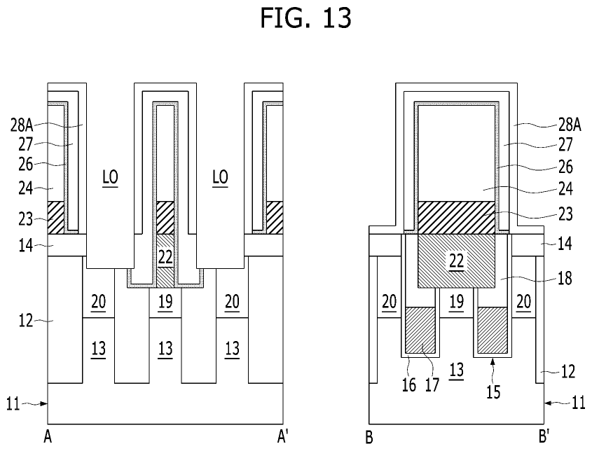

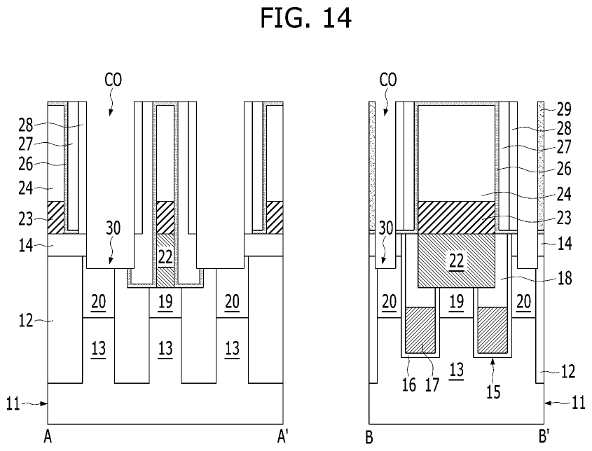

As shown in FIGS. 13 and 14, a second boron-free nitride layer 28 may be formed on the boron nitride layer 27. The second boron-free nitride layer 28 may have a line shape extending along both sidewalls of the bit line structure. The second boron free nitride layer 28 may directly contact the upper surface of the boron nitride layer 27.

The second boron-free nitride layer 28 may include the same material as the first boron-free nitride layer 26. The second boron-free nitride layer 28 may include silicon nitride. For example, the silicon nitride may include silicon nitride of the chemical formula Si3N₄. The second boron-free nitride layer 28 may prevent oxidation and damage of the boron nitride layer 27 due to a thermal process and/or exposure during a semiconductor process, and may be referred to as a ‘capping layer’ or an ‘antioxidation layer’. The thickness of the second boron-free nitride layer 28 may be greater than the thickness of the first boron-free nitride layer 26. The thickness of the second boron-free nitride layer 28 may be equal to or smaller than the thickness of the boron nitride layer 27. For example, the thickness of the second boron-free nitride layer 28 may include a thickness of 50 Å to 70 Å. In this embodiment of the present invention, the thickness of the second boron-free nitride layer 28 may be smaller than the thickness of the boron nitride layer 27.

An etch-back process may be performed to form the second boron-free nitride layer 28 after depositing the second boron-free nitride pre-layer 28A on the boron nitride layer 27 and the bit line structure. The second boron-free nitride pre-layer 28A may include silicon oxide. The bottom surface of the second boron-free nitride layer 28 may be at the same level as the bottom surface of the bit line 23. The upper surface of the second boron-free nitride layer 28 may be at a higher level than the upper surface of the bit line hard mask 24.

Accordingly, a spacer structure in which the first boron-free nitride layer 26, the boron nitride layer 27, and the second boron-free nitride layer 28 are stacked may be formed. The spacer structure may include different structures depending on the height of the bit line structure. Specifically, a stacked structure of the first boron-free nitride layer 26 and the boron nitride layer 27 may be formed on both sidewalls of the bit line contact plug 22, that is, the gap 25. A stacked structure of the first boron-free nitride layer 26, the boron nitride layer 27, and the second boron-free nitride layer 28 may disposed on both sidewalls of the bit line 23 and the bit line hard mask 24.

Subsequently, a plurality of plug separation layers 29 may be formed over the second boron-free nitride layer 28. The plug separation layers 29 may separate each of the line-type openings LO between bit line structures into a plurality of contact openings CO. Referring to FIG. 3, the plug separation layer 29 may vertically overlap with the buried word line 17 over the buried word line 17 in the direction of the line A-A′. The plug separation layers 29 may include silicon nitride or a low-k material. In another embodiment of the present invention, a portion of the bit line hard mask 24 may be consumed during a formation of the plug separation layers 29.

In order to form the plug separation layers 29, a sacrificial material (not shown) such as an oxide filling between the bit line structures may be formed on the second boron-free nitride pre-layer 28A. In addition, a line-shaped mask pattern (not shown) extending in a direction perpendicular to the bit line structure may be formed on the sacrificial material and the bit line structure. In addition, the sacrificial material may be etched using the mask pattern and the bit line structure, and the plug separation material may be gap-filled in the region where the sacrificial material is etched. Thereafter, a plurality of contact openings CO may be formed between the plug separation layers 29 by removing the remaining sacrificial material.

As shown in FIG. 3, when viewed from the top, the contact openings CO and the plug separation layers 29 may be alternately formed between the bit lines 23 and adjacent bit lines 23 in the direction in which the bit lines 23 extend. The adjacent contact openings CO may be arranged in an isolated shape by the bit line structure and the plug separation layers 29. When viewed from the top, the contact opening CO may have a rectangular hole shape.

The lower materials may be etched so as to self-align with the contact openings CO. Accordingly, a plurality of recess regions 30 exposing a portion of the active region 13 may be formed between the bit line structures. Anisotropic etching or a combination of anisotropic etching and isotropic etching may be used to form the recess regions 30. For example, structures exposed through the contact openings CO between the bit line structures may be sequentially and anisotropically etched, and then a portion of the exposed active region 13 may be isotropically etched. In another embodiment of the present invention, the hard mask layer 14 may also be isotropically etched. Portions of the active region 13 and the boron nitride layer 27 may be exposed by the recess regions 30.

The recess regions 30 may extend into the substrate 11. While forming the recess regions 30, the device isolation layer 12, the gate capping layer 18, and the second impurity region 20 may be recessed to a predetermined depth. The bottom surfaces of the recess regions 30 may be at a lower level than the upper surface of the bit line contact plug 22. The bottom surfaces of the recess regions 30 may be at a higher level than the bottom surfaces of the bit line contact plug 22. The contact openings CO and the recess regions 30 may be interconnected. The vertical structure of the contact openings CO and the recess regions 30 may be referred to as a ‘storage node contact hole’.

A dielectric structure (or a spacer structure) may be formed on the sidewall of the bit line structure by the etching process of forming the recess regions 30. The dielectric structure may include materials having different dielectric constants and different silicon contents.

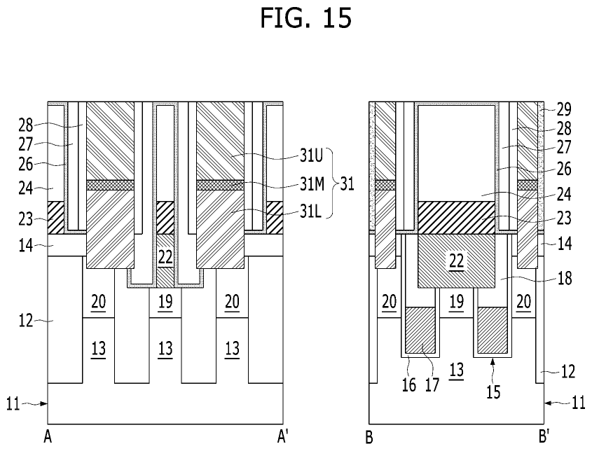

As shown in FIG. 15, a storage node contact plug 31 may be formed. The storage node contact plug 31 may fill the contact openings CO and the recess regions 30. The storage node contact plug 31 may contact the second impurity region 20. The storage node contact plug 31 may be adjacent to the bit line structure. When viewed from top, a plurality of storage node contact plugs 31 may be positioned between a plurality of bit line structures. In a direction parallel to the bit line 23, a plurality of storage node contact plugs 31 and a plurality of plug separation layers 29 may be alternately positioned between neighboring bit lines 23.

In the storage node contact plug 31, a lower plug 31L, an ohmic contact layer 31M, and an upper plug 31U may be sequentially stacked.

The lower plug 31L may include a silicon-containing material. The lower plug 31L may include polysilicon. Polysilicon may be doped with impurities. The lower plug 31L is connected to the second impurity region 20. The upper surface of the lower plug 31L may be located at a higher position than the upper surface of the bit line 23. After depositing polysilicon to fill the contact opening CO and the recess region 30 to form the lower plug 31L, planarization and etch-back processes may be sequentially performed.

An ohmic contact layer 31M may be formed on the lower plug 31L. The ohmic contact layer 31M may include a metal silicide. To form the ohmic contact layer 31M, the deposition and annealing of a silicideable metal layer are performed. Accordingly, silicidation occurs at the interface between the silicideable metal layer and the lower plug 31L, thereby forming a metal silicide layer. The ohmic contact layer 31M may include cobalt silicide. In this embodiment of the present invention, the ohmic contact layer 31M may include cobalt silicide of ‘CoSi₂ phase’.

When cobalt silicide of the CoSi₂ phase is formed as the ohmic contact layer 31M, the contact resistance may be improved and a low resistance cobalt silicide may be formed.

An upper plug 31U is formed on the ohmic contact layer 31M. A metal material (not shown) may be gap-filled and planarized to form the upper plug 31U. The upper plug 31U may include a metal-containing layer. The upper plug 31U may include a material containing tungsten. The upper plug 31U may include a tungsten layer or a tungsten compound. In another embodiment, the upper end of the upper plug 31U may extend to overlap the upper surface of the bit line hard mask 24.

Since the lower plug 31L contains polysilicon, and the ohmic contact layer 31M and the upper plug 31U contain a metal material, the storage node contact plug 31 may be referred to as a hybrid plug or a semi-metal plug.

Subsequently, a memory element (refer to ‘230’ in FIG. 4A) may be formed over the upper plug 31U. In another embodiment, a landing pad may be further formed between the upper plug 31U and the memory element.

As described above, in this embodiment, by applying the boron nitride layer 27 having a dielectric constant of about 1 to 2 as a spacer structure, the spacer structure may have a significantly lower permittivity compared to when SiBN having a dielectric constant of about 4 to 5.2 and/or silicon oxide having a dielectric constant of about 3.9 to 4.3 are applied as a spacer structure. Accordingly, the parasitic capacitance between the bit line structure and the storage node contact plug 31 adjacent to the bit line structure may be reduced. In addition, the boron nitride layer 27 has a dielectric constant similar to an air gap having a dielectric constant of about 1, and may significantly lower the process difficulty than when forming an air gap, thus simplifying the semiconductor process.

Moreover, in this embodiment, it is possible to prevent boron from being out-diffused and being oxidized or damaged at the same time as the spacer structure is formed by stacking the first boron-free nitride layer 26, the boron nitride layer 27, and the second boron-free nitride layer 28.

Various embodiments have been described for the problem to be solved above, but it will be readily appreciated by one of ordinary skill in the art that it is apparent that various changes and modifications may be made thereto without departing from the scope of the disclosure.

What is claimed is:

1. A semiconductor device, comprising:
a conductive line formed over a substrate; and
a multi-layered spacer covering both sidewalls of the conductive line,
wherein the multi-layered spacer is stacked in the order of a diffusion barrier material, a boron nitride layer, and an antioxidant material.

2. The semiconductor device of claim 1, wherein the boron nitride layer is silicon-free nitride.

3. The semiconductor device of claim 1, wherein the boron nitride layer is amorphous.

4. The semiconductor device of claim 1, wherein the boron nitride layer has a higher boron content than a nitride content.

5. The semiconductor device of claim 1, wherein the boron nitride layer has a thickness of 50 Å to 100 Å.

6. The semiconductor device of claim 1, wherein the diffusion barrier material includes a boron-free nitride.

7. The semiconductor device of claim 1, wherein the diffusion barrier material includes silicon nitride.

8. The semiconductor device of claim 1, wherein a thickness of the diffusion barrier material is smaller than thicknesses of the boron nitride layer and the antioxidant material.

9. The semiconductor device of claim 1, wherein the diffusion barrier material has a thickness of 5 Å to 10 Å.

10. The semiconductor device of claim 1, wherein the antioxidant material includes boron-free nitride.

11. The semiconductor device of claim 1, wherein the antioxidant material includes silicon nitride.

12. The semiconductor device of claim 1, wherein the antioxidant material has a thickness equal to or less than a thickness of the boron nitride layer.

13. The semiconductor device of claim 1, wherein the antioxidant material has a thickness of 50 Å to 70 Å.

14. A semiconductor device, comprising:
a bit line structure extended in a direction on a substrate; and
a multi-layered spacer covering both sidewalls of the bit line structure,
wherein the multi-layered spacer is stacked in the order of a first boron-free nitride layer, a boron nitride layer, and a second boron-free nitride layer.

15. The semiconductor device of claim 14, wherein the boron nitride layer is silicon-free nitride.

16. The semiconductor device of claim 14, wherein the boron nitride layer is amorphous.

17. The semiconductor device of claim 14, wherein the boron nitride layer has a higher boron content than a nitride content.

18. The semiconductor device of claim 14, wherein the boron nitride layer has a thickness of 50 Å to 100 Å.

19. The semiconductor device of claim 14, wherein the first and second boron-free nitride layers include silicon nitride.

20. The semiconductor device of claim 14, wherein a thickness of the first boron-free nitride layer is smaller than a thickness of the second boron-free nitride layer.

21. The semiconductor device of claim 14, wherein the first boron-free nitride layer has a thickness of 5 Å to 10 Å.

22. The semiconductor device of claim 14, wherein the second boron-free nitride layer has a thickness of 50 Å to 70 Å.

23. A method for fabricating a semiconductor device, the method comprising:
forming a conductive line over a substrate; and
forming a multi-layered spacer covering both sidewalls of the conductive line,
wherein the multi-layered spacer is stacked in the order of a diffusion barrier material, boron nitride layer, and an antioxidant material.

24. The method of claim 23, wherein the boron nitride layer is formed by using a boron-containing precursor and nitrogen-containing reactant gas.

25. The method of claim 23, wherein the boron nitride layer is formed by using B₂H₆ as a precursor and NH₃ as a reactant gas.

26. The method of claim 23, wherein flow rates of the boron-containing precursor and the nitrogen-containing reactant are in a ratio of 5 to 7:1.

27. The method of claim 23, wherein the boron nitride layer is formed in an amorphous form.

28. The method of claim 23, wherein the diffusion barrier material and the antioxidant material include boron-free nitride.

29. The method of claim 23, wherein the diffusion barrier material and the antioxidant material include silicon nitride.

30. The method of claim 23, wherein the diffusion barrier material and the boron nitride layer are formed in-situ in a same chamber.
